(19) United States
(12) Patent Application Publication
(10) Pub. No.: US 2010/0021757 A1
(43) Pub. Date: Jan. 28, 2010

(54) BRIGHT COATINGS FOR ALUMINUM OR STEEL MOTOR VEHICLE WHEELS AND THEIR PRODUCTION

(75) Inventors: Thomas Kraenzler, Salem (DE); Karsten Loehr, Ulm (DE)

Correspondence Address: PATENT CENTRAL LLC;Stephan A. Pendorf, 1401 Hollywood Boulevard, Hollywood, FL, 33020, US

(73) Assignee: DAIMLER AG, Stuttgart (DE)

(21) Appl. No.: 12/523,886

(22) PCT Filed: Jan. 16, 2008
(86) PCT No.: PCT/EP08/00291

§ 371 Date: Jul. 21, 2009

(30) Foreign Application Priority Data
Jan. 30, 2007 (DE) 10 2007 004 570.2

(51) Int. Cl. B32B 15/20; B32B 15/18; B32B 15/04; C23C 16/12; B29C 71/04

(52) U.S. Cl. 428/613; 428/684; 428/621; 428/626; 428/654; 427/532

(57) ABSTRACT

Surface coating having a bright appearance on motor vehicle wheels made of light metal alloy castings or steel, which can comprise a plurality of layers, wherein it has at least one first layer composed of aluminum or aluminum alloy which is applied directly to the wheel surface, which has metallic brightness, and a method for producing a resistant bright coating on aluminum alloy or steel surfaces, which comprises the steps
gas-phase deposition of aluminum or Al alloy to form a first dense and bright coating
electrochemical oxidation of the surface of the first layer and formation of a nanoporous to microporous second layer of aluminum oxide having a thickness in the range from 50 to 1000 nm.

The invention relates to durable and dirt-repellent bright coatings on motor vehicle wheels or motor vehicle rims based on aluminum and methods for the production of these bright coatings on light metal or steel substrates.

A layer of powder varnish usually lies on ordinary aluminum wheels, which varnish is present on the rim and the wheel surface.

However, the trend with rims has recently been highly bright surfaces which cannot be achieved with conventional rims and varnishes. Chromium coating of the surfaces is a possible, but expensive method of production.

Highly bright surfaces can also be achieved by the process of the so-called electropolishing of the aluminum surfaces in the region of the aluminum wheels. Such a method for aluminum wheels is for example known from Alcoa under the trademark Dura-Bright®.

From DE 699 12 966 is known a method for the surface treatment of aluminum wheel products. The main steps of this method comprise the application of a composition to the product for the chemical lightening, the deoxidization of the product surface, the electrochemical generation of a porous oxide on this product surface by contacting with an electrolyte bath containing phosphoric or phosphine acid, and the application of an outer layer based on silicate or siloxane on the porous oxide.

The electrochemical anodization for the production of the oxide layer is however connected strongly to certain alloy compositions. Only a few alloys even form a highly even, highly adhesive and bright surface coating with this treatment. In the region of aluminum wheels, such a method only leads to acceptable results with relatively pure wrought aluminum alloys, which are used for forged rims having high costs. Economic aluminum casting alloys for economic aluminum wheels which are characterized by comparatively high Si parts of over 1 weight % to 12 weight % compared to the wrought alloys, form for example blotchy brownish and dull surfaces with electrochemical anodization. The treatment of the even more economic steel rims through electropolishing is categorically eliminated.

For the production of a durable brightness on the light metal or steel substrate, especially the motor vehicle wheel, it is necessary that the surface is dirt-repellent and as scratch-resistant as possible.

Dirt-repellent coatings or so-called easy-to-clean coatings or varnishes (ETC coatings) are known for the protection of high quality components of glass, plastics and metals and are supposed to prevent contamination or ease the cleaning. The mode of action is different depending on the case of application.

Water-repellent coatings are for example used for glass surfaces. Clean glass is relatively hydrophilic and forms a contact angle of 20° with regard to water. A hydrophobic ETC coating however increases the contact angle to far above 100° with regard to water. This ETC coating offers a considerably reduced wettability, so that aqueous contaminants roll off or can be washed off easily.

From WO 2005 085 374 A1 are known especially scratch-resistant coatings for light metal rims which are based on perhydro silazanes. Scratch-resistant and at the same time dirt-repellent layers are for example known from WO 02088269 A1 or from DE 10 2004 001 288 A1. The latter document describes hydrophilic coatings for surfaces containing one or more polysilazanes and an ionic reagent or mixtures or ionic reagents. The polysilizane is especially a polysilazane of the formula (SiR′R″—NR′″)ₙ, where R′, R″, R′″) can be the same or different and it either is hydrogen or organic or organometallic remainders. In a preferred embodiment, the polysilazane is a perhydro polysilazane (R′═R″═R′″═H). The ionic reagent is preferably a salt of a carboxylic acid, especially a hydroxy carboxylic acid, or a cationic or anionic silane or an oligomer or polymer. The hydrophilic coatings are formed hereby. The effect of the hydrophilic coatings are based on the fact that hydrophobic contaminants adhere poorly or that the surface can be washed easily with aqueous cleansing means.

It is the object of the invention to disclose a method for the production of durable bright coatings on aluminum or steel surfaces, which cannot be approached with electropolishing, and to provide bright coatings with good durability or dirt-repellent properties on light metal or steel wheels.

The object of the invention is solved in a first aspect by a surface coating on motor vehicle wheels of light metal casting alloys or steel, which can comprise several layers, wherein it comprises at least one first layer of a CVD coating of aluminum or aluminum alloy applied directly to the wheel surface with the characteristics of claim 1.

In a further aspect, the invention is solved by a method for the production of a durable bright coating on aluminum alloy or steel surfaces comprising the steps
gas phase deposition of aluminum or Al alloy for the formation of a first dense layer
electrochemical oxidation of the surface of the first layer and formation of a nanoporous to microporous second layer of aluminum oxide with a thickness in the region of 50 to 1000 nm, with the characteristics of claim 11.

It is essential for the invention that the surface of the substrate or of the aluminum alloy or steel surfaces themselves do not have to have any brightness. Rather, a thin metallic layer is initially applied to these surfaces, which has the bright properties. According to the invention, this is a first layer of aluminum or aluminum alloy applied directly to the wheel surface. According to the method, it is provided to deposit the first layer of bright aluminum or aluminum alloy via the gas phase. The first layer is especially a CVD or PVD coating of aluminum or aluminum alloy.

It is an advantage of the invention that the optical appearance of expensive forged aluminum rims will thus also become possible in an economic manner with inexpensive cast aluminum rims or even steel rims.

With the type of the bright coating of Al or Al alloy, high demands do not have to be made on the alloys used as substrate. The use of light metal alloys, Al casting alloys or steel does not cause any difficulties. The chosen alloys do not have to be accessible for electropolishing, as the Al or Al alloy coating develops the bright effect.

The thickness of the first layer is preferably 10 to 500 μm. The thickness on cast aluminum rims or steel rims is especially preferred 30 to 100 μm.

Regarding the choice of the Al alloy, it has been shown that pure aluminum is superior to most other corrosion protection layers due to its ductility and its passivity, and thus finds preferred use.

For the application of motor vehicle wheels which are subjected to heavy contaminations, abrasive cleaning processes and corrosive media, the first layer of Al or Al alloy is often not durable enough. In a further arrangement of the invention, the surface of the first layer thus carries a second layer in the form of an electrochemically generated microporous or nanoporous oxide layer. This layer is a coating comparable to the electropolishing of aluminum surfaces. The metallic surface is passivated by the oxide layer adhering in a rigid manner and is protected against a further corrosive attack. By suitable choice of the method parameters during the electropolishing or the electrochemical generation of the nanoporous or microporous oxide layer, a surface structure can be generated which has a lotus effect or a dirt-repellent effect.

Furthermore, this layer forms a good adherence basis for further organic coatings.

The thickness of the oxide layer has to be limited in such a manner that the brightness of the surface is not lost. This second layer preferably has a thickness in the region of 50 to 1000 nm.

The protection of the coated wheel or rim with a finishing varnish layer is especially advantageous. In a further advantageous arrangement of the invention, the first or the second layer thus has a third layer of a finishing varnish layer, especially a clear varnish or an easy-to-clean varnish (ETC varnish).

By the combination with an ETC coating, an optically high quality surface is achieved with a simultaneous highest protection against corrosion and durable brightness.

By an optional ETC coating for example with organo silicates, the problem of the rim contamination can be effectively fought by means of brake dust.

The ETC coating can be hydrophilic or hydrophobic coatings. The optimum choice is amongst others dependent on the choice of the brake pad material in the vehicle brake.

In a preferred arrangement of the invention, the third layer is mainly formed of silane, silazane and/or silicone polymers.

The components hereby form the main component of the coating. Further components can especially be fillers increasing the scratch-resistance, hydrophobic or hydrophobilizing additives or catalytically active additives. Silicate powder, clay minerals, aluminum oxide nanopowders or Si nanofillers are especially important as fillers. Titanium oxide is of special importance as a catalytically active additive, which acts in an oxidizing manner on the dirt particles deposited on the surface by UV exposure to light. The combination of hydrophilizing additives and catalytically active titanium oxide is particularly advantageous.

A well-suited third coating is further composed of siloxane with silicate fillers.

In a further arrangement, the third layer comprises perhydro silazane polymers and hydrophilic (co)polymers as additives and/or additives as the main component. A combination of perhydro silazane polymers, hydrophilic (co)polymers and catalytically active titanium oxide proves to be an especially effective scratch-resistant and dirt-repellent coating or easy-to-clean varnish on the bright layer or the electropolished bright layer.

In a preferred arrangement, the surface coating of 1, 2 or 3 layers is applied to a vehicle wheel of an Al casting alloy with an Si part in the region of 3 to 12 weight %.

A further aspect of the invention is a method for the production of a durable bright coating on aluminum alloy or steel surfaces which comprises the following essential steps:
the gas phase deposition of aluminum or Al alloy for the formation of a first dense and bright layer
the electrochemical oxidation of the surface of the first layer and the formation of a nanoporous to microporous second layer of aluminum oxide with a thickness in the region of 50 to 1000 nm.

By the gas phase deposition, the formation of a homogeneously well adhering bright coating on different Al or steel alloys is possible. The following electrochemical oxidation increases the corrosion resistance of the surface and improves the surface quality for a subsequent coating.

For the generation of the bright coatings, it is especially important that even and error-free and chemically pure surface coatings with high smoothness are produced. CVD and PVD methods are especially suitable for this.

A pure aluminum layer having a thickness of 10 to 300 μm is preferably applied within the scope of the gas phase deposition, which is preferably carried out as CVD or PVD method (chemical vapor deposition or physical vapor deposition).

A cold gas process is preferably used as CVD process, especially when depositing on light metal substrates or aluminum wheels. For the deposition, the aluminum surfaces are thereby brought to a temperature in the region of 280 to 350° C., and the steel surfaces are brought to a temperature in the region of 280 to 580° C. The cold gas process is characterized in that the carrier gas loaded with the gaseous Al carrier substances has a lower temperature than the substrate to be coated. The carrier gas temperature is particularly considerably below the decomposition or deposition temperature of the Al carrier substance.

A coating on all sides of a cast aluminum rim or steel rim with a pure aluminum layer having a layer thickness of 30 up to the most of 100 μm is applied by a low temperature CVD method.

The implementation of the particularly suitable CVD methods is already known in principle and is for example described in WO 2005 028 704 A1.

The second layer of aluminum oxide is preferably produced in such a manner that the bright layer of deposited Al or Al alloy is anodized.

The parameters of the anodization are preferably adjusted in such a manner that nano- or microstructures of columnar aluminum oxide form. Due to the interspaces of adjacent columns, the coating as such is configured in a nanoporous or microporous manner.

In a preferred further arrangement, a clear varnish or an easy-to-clean coating is applied to the first, but particularly to the second layer.

The application can take place in a wet method or also as powder coating.

The method is especially suitable for coating Al alloy casting wheels for passenger vehicles or for steel wheels for trucks or buses.

1. A surface coating with bright appearance on a motor vehicle wheel, wherein said wheel is made of light metal alloy castings or steel, which surface coating comprises one or more layers, wherein said surface coating has at least a first layer of aluminum or aluminum alloy which is applied directly to the wheel surface, which surface coating has metallic brightness.

2. The surface coating according to claim 1, wherein the layer of aluminum or aluminum alloy is a CVD or PVD coating.

3. The surface coating according to claim 1, wherein the surface of the first layer has a second layer in the form of an electrochemically generated microporous or nanoporous oxide layer.

4. The surface coating according to claim 1, wherein the surface of the first layer is optionally provided with a second layer in the form of an electrochemically generated microporous or nanoporous oxide layer, and further comprising a layer of a clear varnish or an easy-to-clean varnish.

5. The surface coating according to claim 3, wherein the second layer has a thickness in the region of 50 to 1000 nm.

6. The surface coating according to claim 1, wherein the layer of a clear varnish or an easy-to-clean varnish consists mainly of silane, silazane and/or silicone polymers.

7. The surface coating according to claim 6, wherein the layer of a clear varnish or an easy-to-clean varnish contains hydrophobic additives.

8. The surface coating according to claim 1, wherein the layer of a clear varnish or an easy-to-clean varnish comprises perhydro silazane polymers, hydrophilic copolymers and/or additives, as well as titanium oxide.

9. The surface coating according to claim 1, wherein the motor vehicle wheel consists of an Al alloy casting with 3 to 12 weight % Si.

10. The surface coating according to claim 1, wherein the motor vehicle wheel consists of steel.

11. A method for the production of a durable bright coating on aluminum alloy or steel surfaces comprising the steps of
gas phase deposition of aluminum or Al alloy for the formation of a first dense and bright layer, and
electrochemical oxidation of the surface of the first layer and formation of a nanoporous to microporous second layer of aluminum oxide with a thickness in the region of 50 to 1000 nm.

12. The method according to claim 11, wherein the gas phase deposition takes place by means of a CVD or PVD method.

13. The method according to claim 12, wherein a cold gas process is used as CVD process, where the aluminum surfaces have a temperature in the region of 280 to 350° C., and the steel surfaces a temperature in the region of 280 to 580° C.

14. The method according to claim 11, wherein the electrochemical oxidation takes place by means of anodization.

15. The method according to claim 11, wherein a clear varnish or an easy-to-clean coating is applied to the first or second layer.

16. A motor vehicle wheel of an aluminum alloy or of steel, having a durable bright coating produced by
gas phase deposition of aluminum or Al alloy for the formation of a first dense and bright layer, and
electrochemical oxidation of the surface of the first layer and formation of a nanoporous to microporous second layer of aluminum oxide with a thickness in the region of 50 to 1000 nm.

17. The motor vehicle wheel according to claim 16, wherein the layer of aluminum or aluminum alloy is a CVD or PVD coating.

18. The motor vehicle wheel according to claim 16, further comprising a layer of a clear varnish or an easy-to-clean varnish.

19. The motor vehicle wheel according to claim 18, wherein the layer of a clear varnish or an easy-to-clean varnish consists mainly of silane, silazane and/or silicone polymers.

20. The motor vehicle wheel according to claim 18, wherein the layer of a clear varnish or an easy-to-clean varnish comprises perhydro silazane polymers, hydrophilic copolymers and/or additives, as well as titanium oxide.
